(19) United States
(12) Patent Application Publication
(10) Pub. No.: US 2016/0260662 A1
(43) Pub. Date: Sep. 8, 2016

(54) Systems and Methods for Main Distribution on an Integrated Circuit

(71) Applicant: Avago Technologies General IP (Singapore) Pte. Ltd., Singapore (SG)

(72) Inventors: Donald E. Hawk, King of Prussia, PA (US); Larry Golick, Nazareth, PA (US); Bei Qi Wang, Shanghai (CN)

(21) Appl. No.: 14/638,931

(22) Filed: Mar. 4, 2015

(51) Int. Cl. H01L 23/50; H01L 23/495; H01L 23/00

(52) U.S. Cl. CPC H01L 23/50; H01L 24/48; H01L 24/49; H01L 23/49503; H01L 23/49541; H01L 2224/45014; H01L 2224/4502; H01L 2924/14; H01L 2224/48247

(57) ABSTRACT

Systems, methods, devices, circuits for distributing signals and/or potentials on an integrated circuit.

### FIELD OF THE INVENTION

Systems, methods, devices, circuits for distributing signals and/or potentials on an integrated circuit.

### BACKGROUND

Distribution of signals on an integrated circuit is essential for proper operation of the integrated circuit. In some cases, signals are distributed through traces deposited and etched on the integrated circuit. In some cases, such deposition and etching may not be possible where a signal has a large number of connections and/or where the signal is a power or ground required to transfer significant current.

Hence, for at least the aforementioned reasons, there exists a need in the art for advanced systems and methods for signal distribution on an integrated circuit.

### SUMMARY

Systems, methods, devices, circuits for distributing signals and/or potentials on an integrated circuit.

As just one of many examples, an embodiment is disclosed that provides integrated circuits including: a package die paddle, a die, and a conductive element. The package die paddle having at least a first side, a second side, and a third side, where the first side is adjacent to the second side, and the first side is non-adjacent to the third side. The die is attached to the die paddle. The conductive element extends over the die from the first side to the third side, where one end of the conductive element is electrically connected to the package die paddle at a first connection location on the first side, and another end of the conductive element is electrically connected to the package die paddle at a second connection location. The second connection location is on one of the second side or the third side.

This summary provides only a general outline of some embodiments of the invention. The phrases “in one embodiment,” “according to one embodiment,” “in various embodiments”, “in one or more embodiments”, “in particular embodiments” and the like generally mean the particular feature, structure, or characteristic following the phrase is included in at least one embodiment of the present invention, and may be included in more than one embodiment of the present invention. Importantly, such phases do not necessarily refer to the same embodiment. Many other embodiments of the invention will become more fully apparent from the following detailed description, the appended claims and the accompanying drawings.

### BRIEF DESCRIPTION OF THE FIGURES

A further understanding of the various embodiments of the present invention may be realized by reference to the figures which are described in remaining portions of the specification. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1a shows a multi-dimensional view of a ribbon based signal distribution in accordance with some embodiments of the present invention;

FIG. 1b depicts a cross-sectional view of the ribbon based signal distribution of FIG. 1a;

FIG. 2a shows multi-dimensional view of another ribbon based signal distribution in accordance with some embodiments of the present invention;

FIG. 2b depicts a cross-sectional view of the ribbon based signal distribution of FIG. 2a;

FIG. 3a shows a multi-dimensional view of yet another ribbon based signal distribution in accordance with some embodiments of the present invention;

FIG. 3b depicts a cross-sectional view of the ribbon based signal distribution of FIG. 3a;

FIG. 4 shows a top view of a cross chip ribbon based approach in accordance with one or more embodiments of the present invention;

FIG. 5 shows a top view of a combination of a cross chip ribbon and an angle ribbon based approach in accordance with various embodiments of the present invention; and

FIG. 6 is a flow diagram showing a method for ribbon based signal distribution in accordance with some embodiments of the present invention.

### DETAILED DESCRIPTION OF SOME EMBODIMENTS

Systems, methods, devices, circuits for distributing signals and/or potentials on an integrated circuit.

Some embodiments provide integrated circuits that include: a package die paddle, a die, and a conductive element. The package die paddle having at least a first side, a second side, and a third side, where the first side is adjacent to the second side, and the first side is non-adjacent to the third side. The die is attached to the die paddle. The conductive element extends over the die from the first side to the third side, where one end of the conductive element is electrically connected to the package die paddle at a first connection location on the first side, and another end of the conductive element is electrically connected to the package die paddle at a second connection location. The second connection location is on one of the second side or the third side. In some instances of the aforementioned embodiments, the conductive element is electrically coupled to a voltage potential. This voltage potential may be, for example, a core ground or a core power supply.

In one or more instances of the aforementioned embodiments, the die includes at least one internal bonding site, wherein the conductive element has a broad side (sometimes called a flat side) and a height side where the broad side is at least twice the width of the height side, and the internal bonding site is electrically connected to the broad side of the conductive element by wire bonding. In some such instances, the internal bonding site is nearer to a center of the die than to an edge of the die. In other instances of the aforementioned embodiments, the die includes at least one internal bonding site where the conductive element has a broad side and a height side where the broad side is wider than the height side, the internal bonding site is electrically connected to a conductive stud, and the conductive element lies atop the conductive stud such that the broad side of the conductive element is electrically connected to the conductive stud. In some such instances, the internal bonding site is nearer to a center of the die than to an edge of the die.

In various instances of the aforementioned embodiments, the conductive element is a first conductive element. In such instances, the integrated circuit further includes: a first package lead disposed adjacent to the first side; a second package lead disposed adjacent to either of the second side or the third side; and a second conductive element extending over the die from the first package lead to the second package lead. One end of the second conductive element is electrically connected to the first package lead, and another end of the second conductive element is electrically connected to the second package lead. In some cases, the first conductive element is electrically coupled to a core ground, and the second conductive element is electrically connected to a core power supply. In various cases, the die includes at least one internal bonding site where the second conductive element has a broad side and a height side where the broad side is wider than the height side, and where the internal bonding site is electrically connected to the broad side of the conductive element by wire bonding. In particular cases, the internal bonding site is nearer to a center of the die than to an edge of the die. In other cases, the die includes at least one internal bonding site where the second conductive element has a broad side and a height side where the broad side is at least twice the width of the height side, the internal bonding site is electrically connected to a conductive stud, and the conductive element lies atop the conductive stud such that the broad side of the conductive element is electrically connected to the conductive stud.

Other embodiments provide integrated circuits including: a die having at least a first side and a second side, where the first side is opposite the second side; a first package lead disposed closer to the first side than to the second side; a second package lead disposed closer to the second side than to the first side; and a conductive element extending over the die from the first package lead to the second package lead where one end of the conductive element is electrically connected to the first package lead, and another end of the conductive element is electrically connected to the second package lead. In some instances of the aforementioned embodiments, the conductive element is electrically coupled to a voltage potential that may be, for example, a core ground, or a core power supply. In some cases, the die includes at least one internal bonding site where the conductive element has a broad side and a height side where the broad side is wider than the height side, and the internal bonding site is electrically connected to the broad side of the conductive element by wire bonding. In some cases, the internal bonding site is nearer to a center of the die than to an edge of the die. In various instances of the aforementioned embodiments, the die includes at least one internal bonding site where the conductive element has a broad side and a height side where the broad side exhibits a width greater than that of the height side, the internal bonding site is electrically connected to a conductive stud, and the conductive element lies atop the conductive stud such that the broad side of the conductive element is electrically connected to the conductive stud. In some cases, the internal bonding site is nearer to a center of the die than to an edge of the die

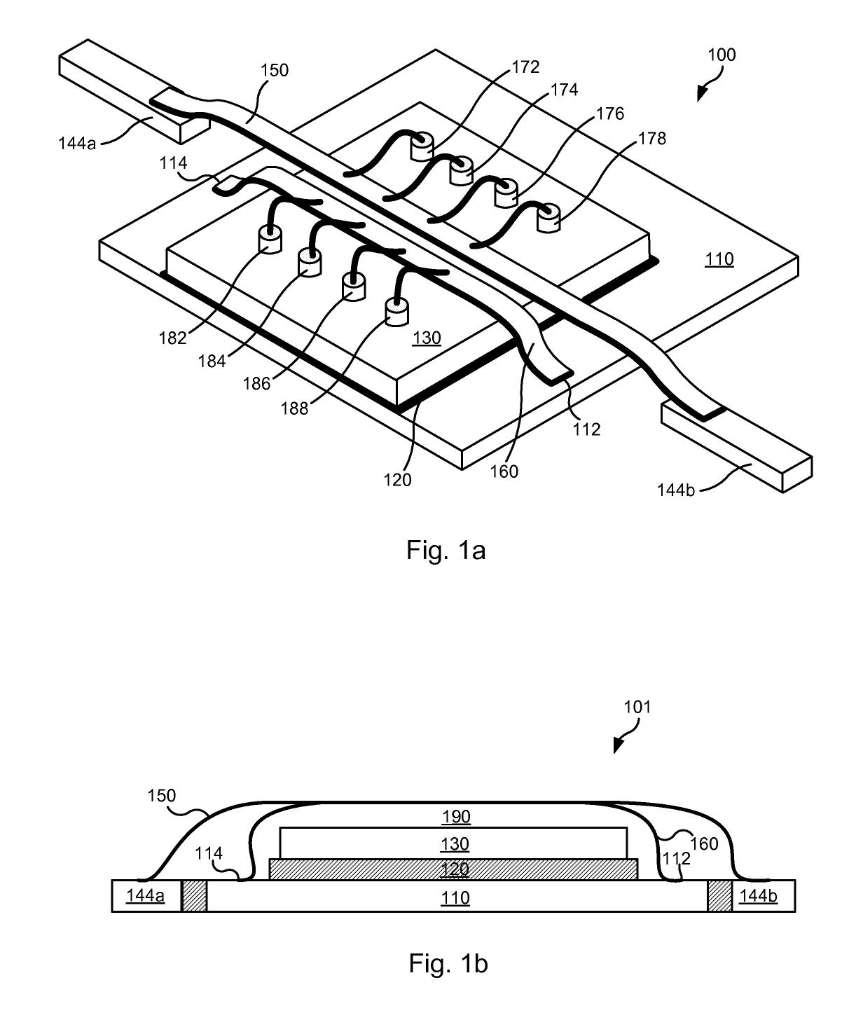

FIG. 1a shows a multi-dimensional view 100 of a ribbon based signal distribution in accordance with some embodiments of the present invention. As shown, a section of a die 130 is installed atop a package die paddle 110 using a dielectric die attach 120. In some cases, die 130 is formed of a semiconductor material with circuit features formed in and on the die using various integrated circuit processing techniques known in the art. At various locations (interior bond sites) signal or voltage potential connections are made to die 130. At these locations of signal or voltage potential connections, ball wedges 172, 174, 176, 178, 182, 184, 186, 188 are formed. Such ball wedges are formed by connecting a conductive material at a location where internal conductive traces of die 130 are exposed. In some cases, ball wedges 172, 174, 176, 178, 182, 184, 186, 188 are formed of metal. In one particular case, the metal is gold. As such, ball wedges 172, 174, 176, 178, 182, 184, 186, 188 provide an electrically conductive path to the respective conductive traces exposed on die 130. In some cases, the conductive traces of die 130 are formed by depositing metal on die 130 using any conductive trace formation method known in the art. Of note, while some embodiments of the present invention use ball-wedge bonding techniques to connect to interior bond sites, other embodiments of the present invention may utilize another technology for bonding to the interior bond sites.

In various cases, one signal or voltage potential is to be connected to a number of different locations in die 130. In such cases, a ribbon 160 corresponding to a common signal or voltage potential is formed by extending ribbon 160 over the top of die 130, and connecting ribbon 160 on opposite sides of die 130. In particular, ribbon 160 is made of a conductive material connected to package die paddle 110 at a contact location 114 on one side of package die paddle 110 and at a contact location 112 on another side of package die paddle 110. In some cases, ribbon 160 is formed of a metal and is wedge bonded onto die paddle 110. As such, ribbon 160 carries the signal or voltage potential of package die paddle 110. Ribbon 160 extends above die 130 and is separated from die 130 by an air gap that serves as a dielectric insulating ribbon 160 from die 130. A number of ball wedges connecting to die 130 at locations to be connected to the signal or voltage potential of ribbon 160 are wirebonded from each of ball wedges 182, 184, 186, 188 to ribbon 160. Such wirebonding is cost effective compared with other types of technologies such as, for example, flip-chip technology. In some cases, ribbon 160 is a flat ribbon rather than the round wire traditionally used for IC package bonding. As used herein, a “flat ribbon” exhibits a “broad side” and a “height side” where the broad side is wider than the flat side. In one particular embodiment, the broad side is at least twice as wide as the height side. Such a flat ribbon facilitates use of standard wire bonding from ribbon 160 to ball wedges 182, 184, 186, 188. This approach to signal and/or power distribution allows the signal or voltage potential of die paddle 110 to be electrically connected to all of the locations on die 130 connected by ball wedges 182, 184, 186, 188. In one particular case, package die paddle 110 is a core ground potential. Based upon the disclosure provided herein, one of ordinary skill in the art will recognize other signals and/or power potentials that may be distributed by way of package die paddle 110.

Another ribbon 150 corresponding to another common signal or voltage potential is formed by extending ribbon 150 over the top of die 130, and connecting ribbon 150 to package leads 144a/144b on opposite sides of die 130. In particular, ribbon 150 is made of a conductive material to package lead 144a on one side of die 130 and at to package lead 144b on another side of die 130. In some cases, ribbon 150 is formed of a metal and is wedge bonded onto package leads 144a/144b. As such, ribbon 150 carries the signal or voltage potential of package leads 144a/144b. Ribbon 150 extends above die 130 and is separated from die 130 by an air gap that serves as a dielectric insulating ribbon 150 from die 130. A number of ball wedges connecting to die 130 at locations to be connected to the signal or voltage potential of ribbon 150 are wirebonded from each of ball wedges 172, 174, 176, 178 to ribbon 150. Such wirebonding is cost effective compared with other types of technologies such as, for example, flip-chip technology. In some cases, ribbon 150 is a flat ribbon rather than the round wire traditionally used for IC package bonding. Such a flat ribbon facilitates use of standard wire bonding from ribbon 150 to ball wedges 172, 174, 176, 178. This approach to signal and/or power distribution allows the signal or voltage potential of package leads 144a/144b to be electrically connected to all of the locations on die 130 connected by ball wedges 172, 174, 176, 178. In one particular case, package leads 144a/144b are connected to a core power potential. Based upon the disclosure provided herein, one of ordinary skill in the art will recognize other signals and/or power potentials that may be distributed by way of die 130.

Turning to FIG. 1b, a cross-sectional view 101 of the ribbon based signal distribution of FIG. 1a is shown. As shown, package leads 144a/144b are separated from package die paddle by a dielectric. In some cases, the dielectric is an air gap. Die 130 is installed atop package die paddle 110 using dielectric die attach 120. Ribbon 150 extends over die 130 from package lead 144a to package lead 144b. An air gap 190 separates ribbon 150 from die 130. Ribbon 160 extends over die 130 from contact location 112 on die paddle 110 to contact location 114 on die paddle 110. Air gap 190 separates ribbon 160 from die 130.

Of note, where ribbon 150 and ribbon 160 are used to distribute core power and core ground potentials to interior bond sites on die 130, IR drop and/or ground bounce may be reduced when compared with other power distribution approaches. In some cases, use of the ribbon based distribution approach discussed in relation to FIG. 1 allows for a reduction in the pitch on the periphery while maintaining reasonable IR drops when compared with other technologies that require finer wire diameters for power distribution for a comparable pitch. Additionally or alternatively, an ability to provide power distribution to interior bond sites eliminates IR drops due to power distribution on a trace of die 130 from the edge to the interior location. Further, such an approach is advantageous over lead-on-chip technology where the lead frame is extended over a die as lead-on-chip is limited in the number and location of interior bonds due to the interaction with peripheral wires used for signals and I/O power and ground. It should further be noted that while FIGS. 1a-1b are shown as using two ribbons, that more or fewer than two ribbons may be used in accordance with different embodiments of the present invention.

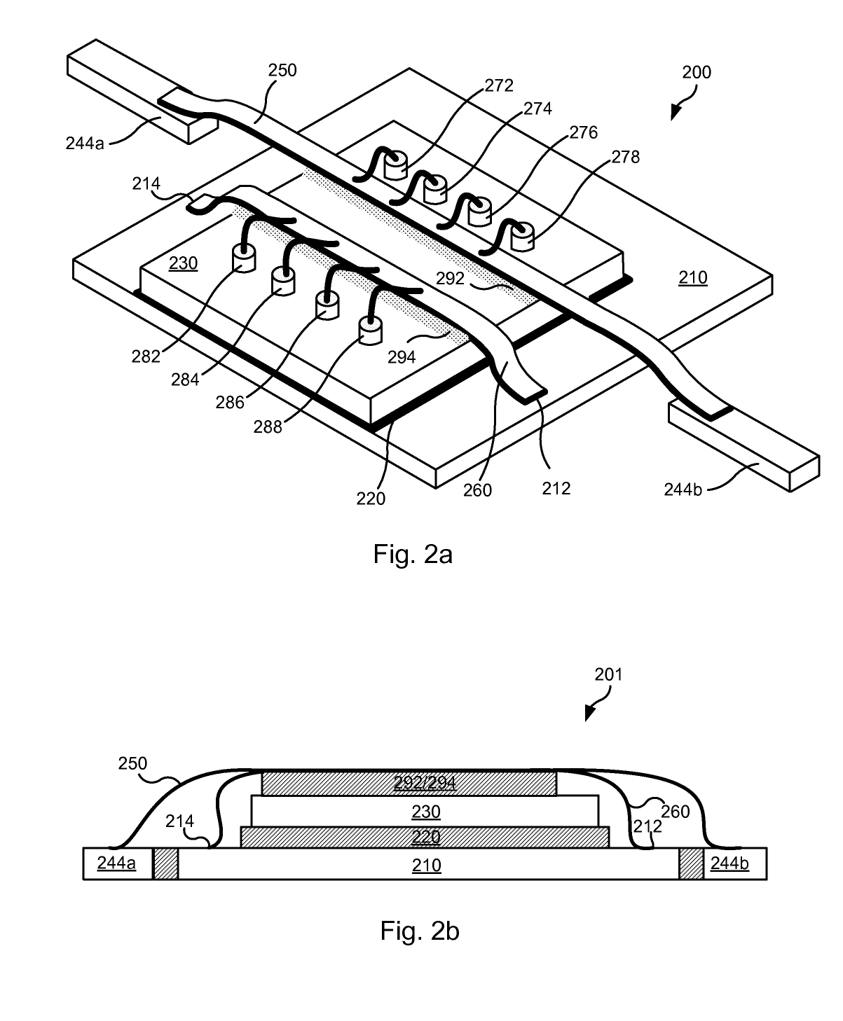

Turning to FIG. 2a a multi-dimensional view 200 of another ribbon based signal distribution is shown in accordance with other embodiments of the present invention. As shown, a section of a die 230 is installed atop a package die paddle 210 using a dielectric die attach 220. In some cases, die 230 is formed of a semiconductor material with circuit features formed in and on the die using various integrated circuit processing techniques known in the art. At various locations (interior bond sites) signal or voltage potential connections are made to die 230. At these locations of signal or voltage potential connections, ball wedges 272, 274, 276, 278, 282, 284, 286, 288 are formed. Such ball wedges are formed by connecting a conductive material at a location where internal conductive traces of die 230 are exposed. In some cases, ball wedges 272, 274, 276, 278, 282, 284, 286, 288 are formed of metal. In one particular case, the metal is gold. As such, ball wedges 272, 274, 276, 278, 282, 284, 286, 288 provide an electrically conductive path to the respective conductive traces exposed on die 230. In some cases, the conductive traces of die 230 are formed by depositing metal on die 230 using any conductive trace formation method known in the art. Of note, while some embodiments of the present invention use ball-wedge bonding techniques to connect to interior bond sites, other embodiments of the present invention may utilize another technology for bonding to the interior bond sites.

In various cases, one signal or voltage potential is to be connected to a number of different locations in die 230. In such cases, a ribbon 260 corresponding to a common signal or voltage potential is formed by extending ribbon 260 over the top of die 230, and connecting ribbon 260 on opposite sides of die 230. In this embodiment, a dielectric material 294 is formed atop die 230 upon which ribbon 260 rests. In particular, ribbon 260 is made of a conductive material connected to package die paddle 210 at a contact location 214 on one side of package die paddle 210 and at a contact location 212 on another side of package die paddle 210. In some cases, ribbon 260 is formed of a metal and is wedge bonded onto die paddle 210. As such, ribbon 260 carries the signal or voltage potential of package die paddle 210. Ribbon 260 extends above die 230 and is separated from die 230 by dielectric material 294 insulating ribbon 260 from die 230. A number of ball wedges connecting to die 230 at locations to be connected to the signal or voltage potential of ribbon 260 are wirebonded from each of ball wedges 282, 284, 286, 288 to ribbon 260. Such wirebonding is cost effective compared with other types of technologies such as, for example, flip-chip technology. In some cases, ribbon 260 is a flat ribbon rather than the round wire traditionally used for IC package bonding. Such a flat ribbon facilitates use of standard wire bonding from ribbon 260 to ball wedges 282, 284, 286, 288 to ribbon 260. This approach to signal and/or power distribution allows the signal or voltage potential of die paddle 210 to be electrically connected to all of the locations on die 230 connected by ball wedges 282, 284, 286, 288. In one particular case, package die paddle 210 is a core ground potential. Based upon the disclosure provided herein, one of ordinary skill in the art will recognize other signals and/or power potentials that may be distributed by way of package die paddle 210.

Another ribbon 250 corresponding to another common signal or voltage potential is formed by extending ribbon 250 over the top of die 230, and connecting ribbon 250 to package leads 244a/244b on opposite sides of die 230. In this embodiment, a dielectric material 292 is formed atop die 230 upon which ribbon 250 rests. In particular, ribbon 250 is made of a conductive material to package lead 244a on one side of die 230 and at to package lead 244b on another side of die 230. In some cases, ribbon 250 is formed of a metal and is wedge bonded onto package leads 244a/244b. As such, ribbon 250 carries the signal or voltage potential of package leads 244a/244b. Ribbon 250 extends above die 230 and is separated from die 230 by dielectric material 292 insulating ribbon 250 from die 230. A number of ball wedges connecting to die 230 at locations to be connected to the signal or voltage potential of ribbon 250 are wirebonded from each of ball wedges 272, 274, 276, 278 to ribbon 250. Such wirebonding is cost effective compared with other types of technologies such as, for example, flip-chip technology. In some cases, ribbon 250 is a flat ribbon rather than the round wire traditionally used for IC package bonding. Such a flat ribbon facilitates use of standard wire bonding from ribbon 250 to ball wedges 272, 274, 276, 278. This approach to signal and/or power distribution allows the signal or voltage potential of package leads 244a/244b to be electrically connected to all of the locations on die 230 connected by ball wedges 272, 274, 276, 278. In one particular case, package leads 244a/244b are connected to a core power potential. Based upon the disclosure provided herein, one of ordinary skill in the art will recognize other signals and/or power potentials that may be distributed by way of die 230.

Turning to FIG. 2b, a cross-sectional view 201 of the ribbon based signal distribution of FIG. 2a is shown. As shown, package leads 244a/244b are separated from package die paddle by a dielectric. In some cases, the dielectric is an air gap. Die 230 is installed atop package die paddle 210 using dielectric die attach 220. Ribbon 250 extends over die 230 from package lead 244a to package lead 244b. Dielectric material 292 separates ribbon 250 from die 230. Ribbon 260 extends over die 230 from contact location 212 on die paddle 210 to contact location 214 on die paddle 210. Dielectric material 294 separates ribbon 260 from die 230. In some cases, dielectric material 292 may be an artifact of manufacturing die 230.

Of note, where ribbon 250 and ribbon 260 are used to distribute core power and core ground potentials to interior bond sites on die 230, IR drop and/or ground bounce may be reduced when compared with other power distribution approaches. In some cases, use of the ribbon based distribution approach discussed in relation to FIG. 2 allows for a reduction in the pitch on the periphery while maintaining reasonable IR drops when compared with other technologies that require finer wire diameters for power distribution for a comparable pitch. Additionally or alternatively, an ability to provide power distribution to interior bond sites eliminates IR drops due to power distribution on a trace of die 230 from the edge to the interior location. Further, such an approach is advantageous over lead-on-chip technology where the lead frame is extended over a die as lead-on-chip is limited in the number and location of interior bonds due to the interaction with peripheral wires used for signals and I/O power and ground. It should further be noted that while FIGS. 2a-2b are shown as using two ribbons, that more or fewer than two ribbons may be used in accordance with different embodiments of the present invention.

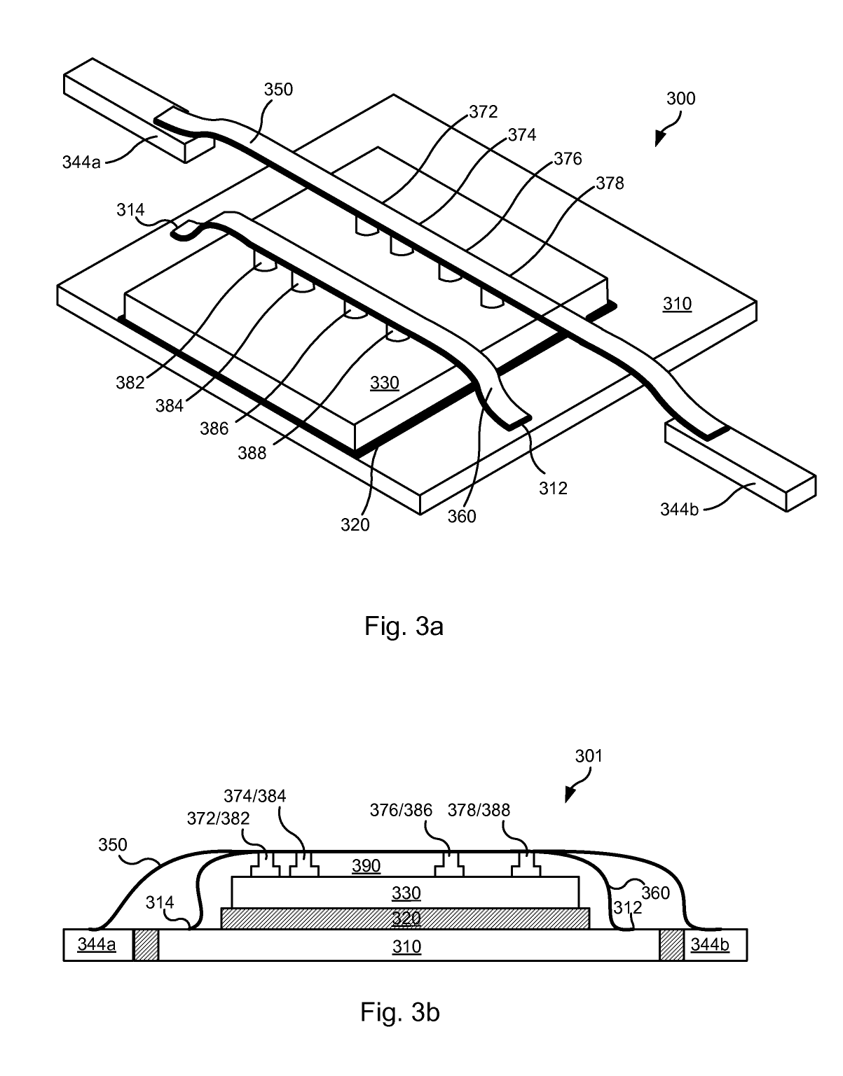

Turning to FIG. 3, a multi-dimensional view 300 of another ribbon based signal distribution is shown in accordance with yet other embodiments of the present invention. As shown, a section of a die 330 is installed atop a package die paddle 310 using a dielectric die attach 320. In some cases, die 330 is formed of a semiconductor material with circuit features formed in and on the die using various integrated circuit processing techniques known in the art. At various locations (interior bond sites) signal or voltage potential connections are made to die 330. At these locations of signal or voltage potential connections, studs 372, 374, 376, 378, 382, 384, 386, 388 are formed. Such studs are formed by depositing or connecting a conductive material at a location where internal conductive traces of die 330 are exposed. In some cases, studs 372, 374, 376, 378, 382, 384, 386, 388 are formed of metal. In one particular case, the metal is gold. As such, studs 372, 374, 376, 378, 382, 384, 386, 388 provide an electrically conductive path to the respective conductive traces exposed on die 330. In some cases, the conductive traces of die 330 are formed by depositing metal on die 330 using any conductive trace formation method known in the art. Of note, while some embodiments of the present invention use ball-wedge boding techniques to connect to interior bond sites, other embodiments of the present invention may utilize another technology for bonding to the interior bond sites.

In various cases, one signal or voltage potential is to be connected to a number of different locations in die 330. In such cases, a ribbon 360 corresponding to a common signal or voltage potential is formed by extending ribbon 360 over the top of die 330 and resting on studs 382, 384, 386, 388 such that an electrical contact is made between the studs and ribbon 360. Ribbon 360 is also connected on opposite sides of die 330. In particular, ribbon 360 is made of a conductive material connected to package die paddle 310 at a contact location 314 on one side of package die paddle 310 and at a contact location 312 on another side of package die paddle 310. In some cases, ribbon 360 is formed of a metal and is wedge bonded onto die paddle 310. As such, ribbon 360 carries the signal or voltage potential of package die paddle 310. At locations between studs 382, 384, 386, 388, ribbon 360 extends above die 330 and is separated from die 330 by an air gap operating as a dielectric insulating ribbon 360 from die 330. In some cases, ribbon 360 is a flat ribbon rather than the round wire traditionally used for IC package bonding. Such a flat ribbon facilitates a sound electrical contact between studs 382, 384, 386, 388 and ribbon 360. This approach to signal and/or power distribution allows the signal or voltage potential of die paddle 310 to be electrically connected to all of the locations on die 330 connected by studs 382, 384, 386, 388. In one particular case, package die paddle 310 is a core ground potential. Based upon the disclosure provided herein, one of ordinary skill in the art will recognize other signals and/or power potentials that may be distributed by way of package die paddle 310. In some cases, subsequent assembly operations may involve molding which would fill the air gap with a molding compound.

Another ribbon 350 corresponding to a common signal or voltage potential is formed by extending ribbon 350 over the top of die 330 and resting on studs 372, 374, 376, 378 such that an electrical contact is made between the studs and ribbon 350. Ribbon 350 is also connected to package leads 344a/344b on opposite sides of die 330. In particular, ribbon 350 is made of a conductive material connected to package leads 344a/344b on either side of package die paddle 310. In some cases, ribbon 350 is formed of a metal and is wedge bonded onto package leads 344a/344b. As such, ribbon 350 carries the signal or voltage potential of package leads 344a/344b. At locations between studs 372, 374, 376, 378 ribbon 350 extends above die 330 and is separated from die 330 by an air gap operating as a dielectric insulating ribbon 350 from die 330. In some cases, ribbon 350 is a flat ribbon rather than the round wire traditionally used for IC package bonding. Such a flat ribbon facilitates a sound electrical contact between studs 372, 374, 376, 378 and ribbon 350. This approach to signal and/or power distribution allows the signal or voltage potential of package leads 344a/344b to be electrically connected to all of the locations on die 330 connected by studs 372, 374, 376, 378. In one particular case, package leads 344a/344b is a voltage potential. Based upon the disclosure provided herein, one of ordinary skill in the art will recognize other signals and/or power potentials that may be distributed by way of package leads 344a/344b.

Turning to FIG. 3b, a cross-sectional view 301 of the ribbon based signal distribution of FIG. 3a is shown. As shown, package leads 344a/344b are separated from package die paddle 310 by a dielectric. In some cases, the dielectric is an air gap. Die 330 is installed atop package die paddle 310 using dielectric die attach 320. Ribbon 350 rests on studs 372, 374, 376, 378 as it extends over die 330 from package lead 344a to package lead 344b. Ribbon 360 rests on studs 382, 384, 386, 388 as it extends over die 330 from contact location 312 on die paddle 310 to contact location 314 on die paddle 310. Dielectric material 394 separates ribbon 360 from die 330.

Of note, where ribbon 350 and ribbon 360 are used to distribute core power and core ground potentials to interior bond sites on die 330, IR drop and/or ground bounce may be reduced when compared with other power distribution approaches. In some cases, use of the ribbon based distribution approach discussed in relation to FIG. 3 allows for a reduction in the pitch on the periphery while maintaining reasonable IR drops when compared with other technologies that require finer wire diameters for power distribution for a comparable pitch. Additionally or alternatively, an ability to provide power distribution to interior bond sites eliminates IR drops due to power distribution on a trace of die 330 from the edge to the interior location. Further, such an approach is advantageous over lead-on-chip technology where the lead frame is extended over a die as lead-on-chip is limited in the number and location of interior bonds due to the interaction with peripheral wires used for signals and I/O power and ground. It should further be noted that while FIGS. 3a-3b are shown as using two ribbons, that more or fewer than two ribbons may be used in accordance with different embodiments of the present invention.

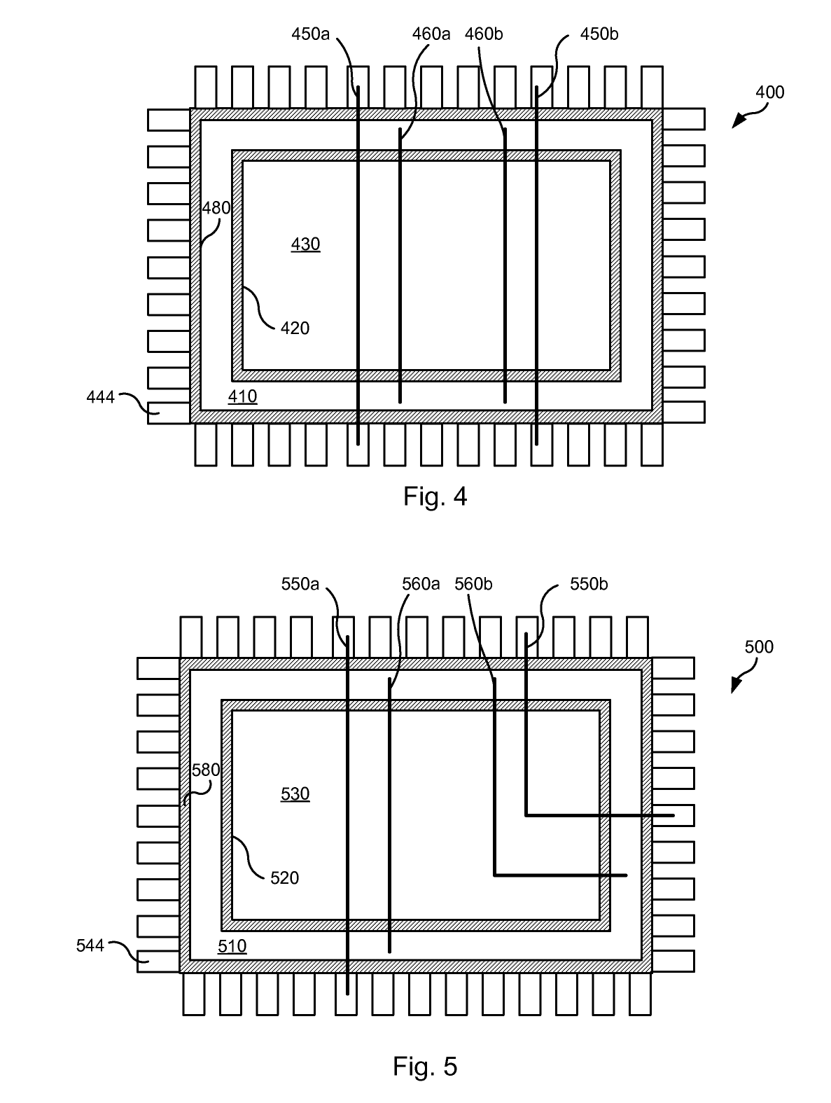

Turing to FIG. 4, a top view 400 of a cross chip ribbon based approach in accordance with one or more embodiments of the present invention. As shown, package leads 444 are separated from a package die paddle 410 by a dielectric 480. In some cases, dielectric 480 is an air gap. A die 430 is attached to package die paddle 410 by a dielectric attach material 420. A ribbon 450a is connected to respective package lead on one side of die 430, extends over die 430, and is attached to another respective package lead on the opposite side of die 430. Another ribbon 450b is connected to respective package lead on one side of die 430, extends over die 430, and is attached to another respective package lead on the opposite side of die 430. A ribbon 460a is connected to package die paddle 410 on one side of die 430, extends over die 430, and is attached to package die paddle on the opposite side of die 430. Another ribbon 460b is connected to package die paddle 410 on one side of die 430, extends over die 430, and is attached to package die paddle on the opposite side of die 430. It should be noted that while the embodiment of FIG. 4 is shown with four ribbons, more or fewer ribbons may be extended over die 430. As discussed above in relation to FIGS. 1-3, each of ribbons 450a, 450b, 460a, 460b are attached to interior bond sites either by wire bonding or by direct contact between the ribbon and studs.

Turing to FIG. 5, a top view 500 of another cross chip ribbon based approach in accordance with one or more embodiments of the present invention. As shown, package leads 544 are separated from a package die paddle 510 by a dielectric 580. In some cases, dielectric 580 is an air gap. A die 530 is attached to package die paddle 510 by a dielectric attach material 520. A ribbon 550a is connected to respective package lead on one side of die 530, extends over die 530, and is attached to another respective package lead on the opposite side of die 530. Another ribbon 550b is connected to respective package lead on one side of die 530, extends over die 530, and is attached to another respective package lead on an adjacent side of die 530. A ribbon 560a is connected to package die paddle 510 on one side of die 530, extends over die 530, and is attached to package die paddle on the opposite side of die 530. Another ribbon 560b is connected to package die paddle 510 on one side of die 530, extends over die 530, and is attached to package die paddle on an adjacent side of die 530. It should be noted that while the embodiment of FIG. 5 is shown with four ribbons, more or fewer ribbons may be extended over die 530. As discussed above in relation to FIGS. 1-3, each of ribbons 550a, 550b, 560a, 560b are attached to interior bond sites either by wire bonding or by direct contact between the ribbon and studs.

It should be noted that other approaches may be used to connect ribbons from one side of die 530 to an adjacent side of die 530. For example, ribbon 550b may be straightened out such that it extends directly (i.e., without the ninety-degree turn shown in FIG. 5b) between the package pins shown as being connected by ribbon 550b in FIG. 5b. Similarly, ribbon 560b may be straightened out such that it extends directly (i.e., without the ninety-degree turn shown in FIG. 5b) between the locations on die paddle 510 shown as being connected by ribbon 560b in FIG. 5b.

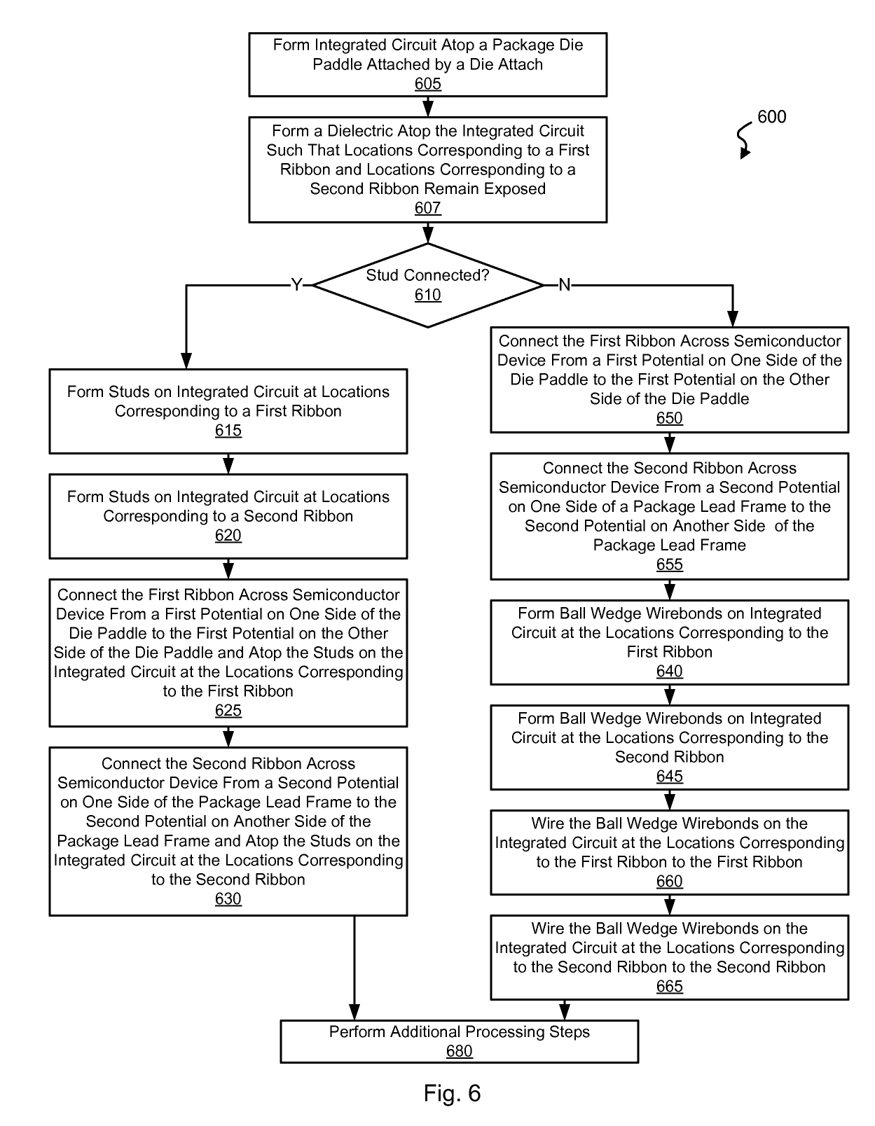

Turning to FIG. 6, a flow diagram 600 shows a method for ribbon based signal distribution in accordance with some embodiments of the present invention. Following flow diagram 600, an integrated circuit is formed atop a package die paddle (block 605). This may include forming an integrated circuit on a semiconductor material using standard deposition and etching techniques that leave one or more interior bond sites exposed. The formed integrated circuit is then attached to a package die paddle using a dielectric die attach material. Additionally, a dielectric is formed atop the integrated circuit such that locations corresponding to a first ribbon and locations corresponding to a second ribbon remain exposed (block 607). This may be done using any processing techniques known in the art. It is then determined whether the interior bond sites are to be attached using stud connectivity or wirebond connectivity (block 610).

Where wirebond connectivity is to be used (block 610), the first ribbon is connected from a first potential on one side of the package die paddle to the same first potential on another side of the package die paddle (block 650). In some cases, the first potential is a core ground. The second ribbon is connected from a second potential on a package lead on one side of a package lead frame to the same second potential on a package lead on another side of the package lead frame (block 655). In some cases, the second potential is a core voltage supply. Ball wedge wirebonds are formed on the integrated circuit at the locations of the interior bond sites that will be serviced by a first ribbon (block 640). Similarly, ball wedge wirebonds are formed on the integrated circuit at the locations of the interior bond sites that will be serviced by a second ribbon (block 645). The ball wedge wirebonds to be serviced by the first ribbon are wire bonded to the first ribbon (block 660), and the ball wedge wirebonds to be serviced by the second ribbon are wire bonded to the second ribbon (block 665).

Alternatively, where stud connectivity is to be used (block 610), studs are formed on the integrated circuit at the locations of the interior bond sites that will be serviced by a first ribbon (block 615). Similarly, studs are formed on the integrated circuit at the locations of the interior bond sites that will be serviced by a second ribbon (block 620). The second ribbon is connected from a first potential on one side of the package die paddle to the same first potential on another side of the package die paddle such that the first ribbon lays over the studs to be operated at the first potential, and thereby making electrical contact with the package die paddle (block 625). Again, in some cases, the first potential is a core ground. The second ribbon is connected from a second potential on a package lead on one side of a package lead frame to the same second potential on a package lead on another side of the package lead frame such that the second ribbon lays over the studs to be operated at the second potential, and thereby making electrical contact with the attached package leads (block 630). Again, in some cases, the second potential is a core voltage supply.

Whether the stud approach or wired approach are used, additional processing steps are performed to complete the device (block 680). This additional processing may include, but is not limited to, forming the remaining peripheral wire bonds to connect the remainder of signals and voltages to remaining package lead elements, and other assemble operations such as molding. Based upon the disclosure provided herein, one of ordinary skill in the art will recognize a variety of additional processing steps that may be performed in accordance with different embodiments of the present invention.

In conclusion, the invention provides novel systems, devices, methods and arrangements for connecting interior bond sites of a die. While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

1. An integrated circuit, the integrated circuit comprising:
a package die paddle having at least a first side, a second side, and a third side, wherein the first side is adjacent to the second side, and the first side is non-adjacent to the third side;
a die attached to the die paddle; and
a conductive element extending over the die from the first side to the third side, wherein one end of the conductive element is electrically connected to the package die paddle at a first connection location on the first side, and another end of the conductive element is electrically connected to the package die paddle at a second connection location, and wherein the second connection location is selected from a group consisting of: the second side, and the third side.

2. The integrated circuit of claim 1, wherein the conductive element is electrically coupled to a voltage potential selected from a group consisting of: a core ground, and a core power supply.

3. The integrated circuit of claim 1, wherein the die includes at least one internal bonding site, wherein the conductive element has a broad side and a height side where the broad side is at least twice the width of the height side, and wherein the internal bonding site is electrically connected to the broad side of the conductive element by ball wedge wire bonding.

4. The integrated circuit of claim 3, wherein the internal bonding site is nearer to a center of the die than to an edge of the die.

5. The integrated circuit of claim 1, wherein the die includes at least one internal bonding site, wherein the conductive element has a broad side and a height side where the broad side is wider than the height side, wherein the internal bonding site is electrically connected to a conductive stud, and wherein the conductive element lies atop the conductive stud such that the broad side of the conductive element is electrically connected to the conductive stud.

6. The integrated circuit of claim 1, wherein the conductive element is a first conductive element, and wherein the integrated circuit further comprises:
a first package lead disposed adjacent to the first side;
a second package lead disposed adjacent to a location selected from a group consisting of: the second side, and the third side; and
a second conductive element extending over the die from the first package lead to the second package lead, wherein one end of the second conductive element is electrically connected to the first package lead, and another end of the second conductive element is electrically connected to the second package lead.

7. The integrated circuit of claim 6, wherein the first conductive element is electrically coupled to a core ground, and the second conductive element is electrically connected to a core power supply.

8. The integrated circuit of claim 6, wherein the die includes at least one internal bonding site, wherein the second conductive element has a broad side and a height side where the broad side is wider than the height side, and wherein the internal bonding site is electrically connected to the broad side of the conductive element by ball edge wire bonding.

9. The integrated circuit of claim 6, wherein the die includes at least one internal bonding site, wherein the second conductive element has a broad side and a height side where the broad side is at least twice the width of the height side, wherein the internal bonding site is electrically connected to a conductive stud, and wherein the conductive element lies atop the conductive stud such that the broad side of the conductive element is electrically connected to the conductive stud.

10. An integrated circuit, the integrated circuit comprising:
a die having at least a first side and a second side, wherein the first side is opposite the second side;
a first package lead disposed closer to the first side than to the second side;
a second package lead disposed closer to the second side than to the first side; and
a conductive element extending over the die from the first package lead to the second package lead, wherein one end of the conductive element is electrically connected to the first package lead, and another end of the conductive element is electrically connected to the second package lead.

11. The integrated circuit of claim 10, wherein the conductive element is electrically coupled to a voltage potential selected from a group consisting of: a core ground, and a core power supply.

12. The integrated circuit of claim 10, wherein the die includes at least one internal bonding site, wherein the conductive element has a broad side and a height side where the broad side is wider than the height side, and wherein the internal bonding site is electrically connected to the broad side of the conductive element by wire bonding.

13. The integrated circuit of claim 12, wherein the internal bonding site is nearer to a center of the die than to an edge of the die.

14. The integrated circuit of claim 10, wherein the die includes at least one internal bonding site, wherein the conductive element has a broad side and a height side where the broad side exhibits a width greater than that of the height side, wherein the internal bonding site is electrically connected to a conductive stud, and wherein the conductive element lies atop the conductive stud such that the broad side of the conductive element is electrically connected to the conductive stud.

15. The integrated circuit of claim 10, wherein the conductive element is a first conductive element, and wherein the integrated circuit further comprises:
a package die paddle, wherein the die is attached to the package die paddle;
a second conductive element extending over the die from a first location on the package die paddle near the first side of the die to a second location on the package die paddle near the second side of the die, wherein a one end of the second conductive element is electrically connected to the package die paddle at the first location.

16. The integrated circuit of claim 15, wherein the first conductive element is electrically coupled to a core power supply, and the second conductive element is electrically connected to a core ground.

17. The integrated circuit of claim 15, wherein the die includes at least one internal bonding site, wherein the second conductive element has a broad side and a height side where the broad side is at least twice the width of the height side, wherein the internal bonding site is electrically connected to a conductive stud, and wherein the conductive element lies atop the conductive stud such that the broad side of the conductive element is electrically connected to the conductive stud.

18. The integrated circuit of claim 17, wherein the internal bonding site is nearer to a center of the die than to an edge of the die.

19. The integrated circuit of claim 16, wherein the die includes at least one internal bonding site, wherein the conductive element has a broad side and a height side where the broad side is wider than the height side, wherein the internal bonding site is electrically connected to a conductive stud, and wherein the conductive element lies atop the conductive stud such that the broad side of the conductive element is electrically connected to the conductive stud.

20. An integrated circuit, the integrated circuit comprising:
a package die paddle having at least a first side, a second side, and a third side, wherein the first side is adjacent to the second side, and the first side is non-adjacent to the third side;
a die attached to the die paddle;
a first package lead disposed adjacent to the first side;
a second package lead disposed adjacent to a location selected from a group consisting of: the second side, and the third side;
a first conductive element extending over the die from the first side to the third side, wherein one end of the first conductive element is electrically connected to the package die paddle at a first connection location on the first side, and another end of the first conductive element is electrically connected to the package die paddle at a second connection location, and wherein the second connection location is selected from a group consisting of: the second side, and the third side; and
a second conductive element extending over the die from the first package lead to the second package lead, wherein one end of the second conductive element is electrically connected to the first package lead, and another end of the second conductive element is electrically connected to the second package lead
